(19) United States
(12) Patent Application Publication
(10) Pub. No.: US 2024/0286404 A1
(43) Pub. Date: Aug. 29, 2024

(54) INKJET APPARATUS AND PRINTER

(71) Applicant: Panasonic Intellectual Property Management Co., Ltd., Osaka (JP)

(72) Inventor: KAZUKI FUKADA, Osaka (JP)

(21) Appl. No.: 18/444,607

(22) Filed: Feb. 16, 2024

(30) Foreign Application Priority Data
Feb. 24, 2023 (JP) 2023-027057

(51) Int. Cl. B41J 2/045; H10N 30/80

(52) U.S. Cl. CPC B41J 2/04581; B41J 2/04541; B41J 2/0455; B41J 2/04573; B41J 2/04588; H10N 30/802

(57) ABSTRACT

An inkjet apparatus of the present disclosure includes a piezoelectric element that is driven by a pulse signal and applies pressure to a pressure chamber containing ink, and a phase controller that includes N (N is an integer more than or equal to 2) parallel wirings provided in parallel with each other and shifts a phase of the pulse signal transmitted by each of the N parallel wirings.

### BACKGROUND

### 1. Technical Field

The present disclosure relates to an inkjet apparatus and a printer that perform printing by discharging liquid such as ink.

### 2. Description of the Related Art

Conventionally, piezoelectric driving inkjet discharge heads have been widely used. For example, PTL 1 discloses an inkjet discharge head that drives an actuator including a piezoelectric element by a pulse generation circuit and a switch circuit.

### CITATION LIST

### Patent Literature

PTL 1: Unexamined Japanese Patent Publication No. 2001-301158

### SUMMARY

An inkjet apparatus according to one aspect of the present disclosure includes a piezoelectric element that is driven by a pulse signal and applies pressure to a pressure chamber containing ink, and a phase controller that includes N (N is an integer more than or equal to 2) parallel wirings provided in parallel with each other and shifts a phase of the pulse signal transmitted by each of the N parallel wirings.

### BRIEF DESCRIPTION OF THE DRAWINGS

FIG. 1 is a diagram illustrating an example of a configuration of a printer according to an embodiment of the present disclosure;

FIG. 2 is a diagram illustrating an example of a configuration of an inkjet apparatus;

FIG. 3 is a diagram for explaining ringing noise included in a generated pulse signal generated by a pulse generator;

FIG. 4 is a diagram for explaining a first example of a configuration of a noise reduction unit;

FIG. 5 is a diagram illustrating a signal at each position of the noise reduction unit in the first example of the configuration of the noise reduction unit;

FIG. 6 is a diagram illustrating a configuration example in a case where a phase controller has four parallel wirings in the first example of the configuration of the noise reduction unit;

FIG. 7 is a diagram illustrating a noise component included in each signal output from four parallel wirings in the first example of the configuration of the noise reduction unit;

FIG. 8 is a diagram for explaining a second example of the configuration of the noise reduction unit;

FIG. 9 is a diagram illustrating a signal at each position of the noise reduction unit in the second example of the configuration of the noise reduction unit;

FIG. 10 is a diagram illustrating a configuration example in a case where the phase controller has four parallel wirings in the second example of the configuration of the noise reduction unit;

FIG. 11 is a diagram for explaining a third example of the configuration of the noise reduction unit; and

FIG. 12 is a view for explaining a variation of the inkjet apparatus provided with a plurality of the pulse generators.

### DETAILED DESCRIPTIONS

In recent years, in the field of printed electronics for forming an electronic device on a substrate by using a printing technique, use of an inkjet discharge head has been studied. Further, use of an inkjet discharge head for industrial applications such as large area painting has been studied. In order to apply an inkjet discharge head to printed electronics and industrial applications, it is desired to make a dischargeable droplet large or to allow a high-viscosity ink to be discharged. For this purpose, a piezoelectric element that causes ink to be discharged from an inkjet discharge head needs to be displaced significantly and fast.

In order to displace a piezoelectric element significantly and fast, the piezoelectric element as a capacitor needs to be rapidly charged and discharged. In a case where a piezoelectric element is rapidly charged and discharged, inrush current is large, and a meniscus surface of a nozzle is disturbed due to ringing noise (switching noise) generated in a voltage waveform applied to the piezoelectric element, and a discharge failure may occur.

An object of the present disclosure is to provide an inkjet apparatus and a printer capable of stably discharging a high-viscosity ink material in a large droplet.

Hereinafter, exemplary embodiments of the present disclosure will be described in detail with reference to the drawings. However, an unnecessarily detailed description such as detailed description of already well-known matters and duplicated description of substantially identical configuration will be sometimes eliminated.

### <Printer 100>

FIG. 1 is a diagram illustrating an example of a configuration of printer 100 according to an exemplary embodiment of the present disclosure. As illustrated in FIG. 1, printer 100 includes inkjet apparatus 1, movement device 2, and controller 3. In printer 100, movement device 2 moves a printing target relative to inkjet apparatus 1, and inkjet apparatus 1 discharges ink onto a printing target to perform printing of the printing target. Controller 3 performs movement control by movement device 2 and operation control of inkjet apparatus 1.

### <Inkjet Apparatus 1>

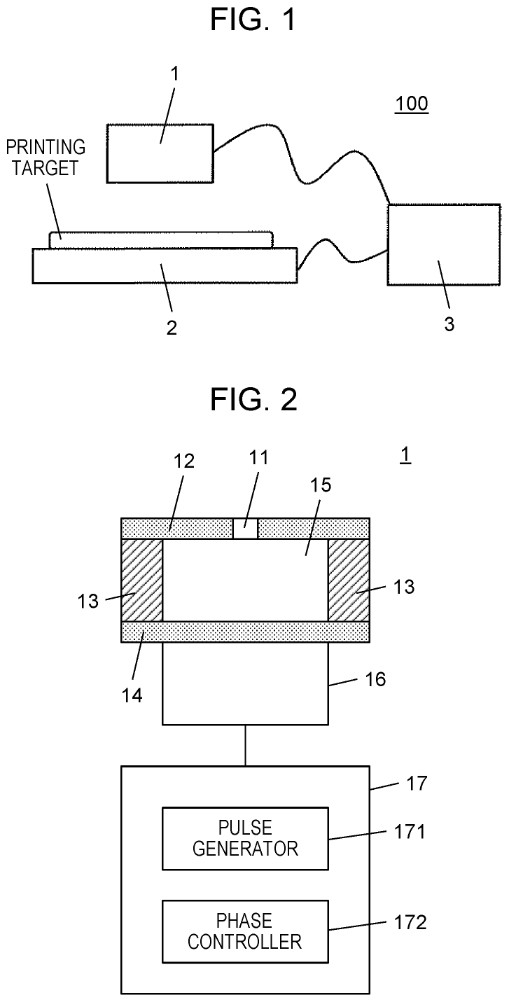

FIG. 2 is a diagram illustrating an example of a configuration of inkjet apparatus 1. Inkjet apparatus 1 includes nozzle plate 12 provided with nozzle 11, side wall 13, diaphragm 14, pressure chamber 15, piezoelectric element 16, and noise reduction unit 17. Pressure chamber 15 includes nozzle plate 12, side wall 13, and diaphragm 14.

Piezoelectric element 16 is driven by an output pulse signal supplied from noise reduction unit 17 and vibrates. Vibration of piezoelectric element 16 is transmitted to diaphragm 14 to apply pressure to pressure chamber 15. When pressure is applied to pressure chamber 15, ink in pressure chamber 15 is pressurized and discharged from nozzle 11.

Noise reduction unit 17 includes pulse generator 171 that generates a pulse signal for driving piezoelectric element 16 on the basis of a control signal supplied from controller 3. Pulse generator 171 may include an amplifier circuit that amplifies a pulse signal to be generated. Note that, in the present disclosure, the amplifier circuit does not need to be included in pulse generator 171, and for example, an amplifier circuit separate from pulse generator 171 may be provided at a subsequent stage of pulse generator 171.

Further, noise reduction unit 17 includes N (N is an integer more than or equal to 2) parallel wirings provided in parallel with each other in order to reduce a noise component of ringing noise that may be generated in a generated pulse signal from a generated pulse signal generated by pulse generator 171, and includes phase controller 172 that shifts a phase of a pulse signal transmitted by each parallel wiring. A plurality of pulse signals whose phases are shifted from each other by phase controller 172 are superimposed on each other and output to piezoelectric element 16 as output pulse signals.

As described above, an output pulse signal in which a noise component of ringing noise is reduced is output from noise reduction unit 17 to piezoelectric element 16. By the above, it is possible to prevent irregular vibration that may occur in piezoelectric element 16 due to ringing noise and ink discharge failure from nozzle 11 that may occur due to irregular vibration.

[Description of Ringing Noise that May Occur in Pulse Signal]

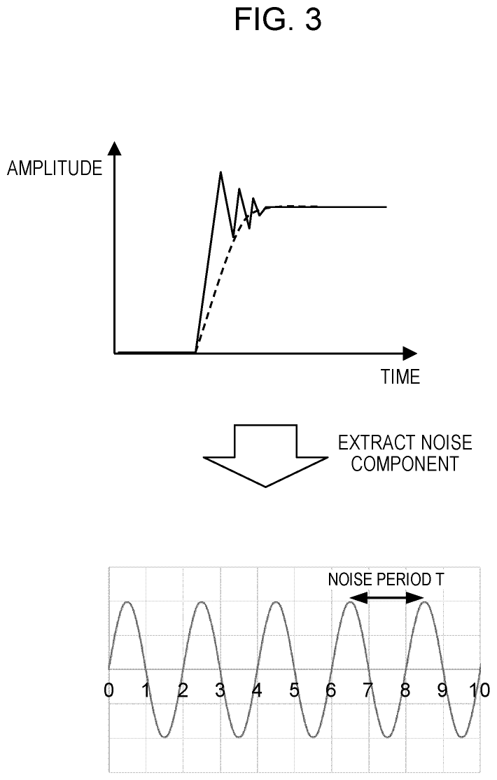

Before description of details of noise reduction unit 17, ringing noise included in a generated pulse signal generated by pulse generator 171 will be described. FIG. 3 is a diagram for explaining ringing noise included in a generated pulse signal generated by pulse generator 171.

An upper graph of FIG. 3 illustrates a relationship between an amplitude and time in each of a generated pulse signal including ringing noise and a virtual pulse signal not including ringing noise. In the upper graph of FIG. 3, a broken line indicates a relationship between an amplitude and time of a pulse signal without ringing noise, and a solid line indicates a relationship between an amplitude and time of a generated pulse signal including ringing noise.

Ringing noise is generally noise generated by reflection of a signal at a constant period between a transmission side and a reception side of the signal. Therefore, ringing noise is periodic noise that fluctuates at a constant period.

A lower graph of FIG. 3 illustrates a state in which a noise component caused by ringing noise is extracted from a generated pulse signal of the upper graph of FIG. 3. In description below, a fluctuation period of a noise component is referred to as noise period T. Note that the lower graph of FIG. 3 shows a state in which an amplitude of a noise component is substantially constant, but an amplitude actually decreases with lapse of time. For example, noise period T is actually measured experimentally using a piezoelectric element and a pulse generator, or calculated by simulation using a computer or the like.

In a case where a pulse signal including ringing noise is input to piezoelectric element 16, displacement of piezoelectric element 16 vibrates based on a noise component as illustrated in the upper graph of FIG. 3. Such vibration of piezoelectric element 16 may cause disturbance in an ink liquid surface (meniscus surface) inside nozzle 11 illustrated in FIG. 2, leading to occurrence of ink discharge failure. In the present disclosure, noise reduction unit 17 can reduce a noise component of ringing noise included in a generated pulse signal.

### [First Example of Configuration of Noise Reduction Unit 17]

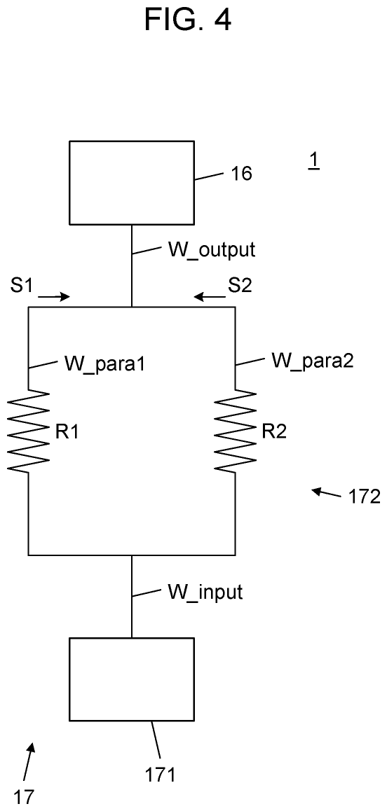

Hereinafter, noise reduction unit 17 will be described in detail. FIG. 4 is a diagram for explaining a first example of a configuration of noise reduction unit 17. In the first example illustrated in FIG. 4, noise reduction unit 17 includes pulse generator 171 and phase controller 172 including input wiring W_input, parallel wirings W_para1 and W_para2, and output wiring W_output.

Input wiring W_input is connected to pulse generator 171. A generated pulse signal generated by pulse generator 171 is distributed to each parallel wiring through input wiring W_input.

Two parallel wirings W_para1 and W_para2 transmit a generated pulse signal. Two parallel wirings W_para1 and W_para2 are connected in parallel to each other and connected in series to input wiring W_input. Two parallel wirings W_para1 and W_para2 are provided with resistors R1 and R2, respectively. Output wiring W_output is connected to a terminal of each of two parallel wirings W_para1 and W_para2. That is, a parallel circuit including two parallel wirings W_para1 and W_para2 is connected in series to piezoelectric element 16 by one output wiring W_output.

A resistance value of resistor R1 disposed on parallel wiring W_para1 and a resistance value of resistor R2 disposed on parallel wiring W_para2 are different from each other. In description below, a resistance value of resistor R1 is referred to as r1[Ω], and a resistance value of resistor R2 is referred to as r2[Ω]. Note that each resistance value includes a resistance (hereinafter, referred to as wiring resistance) originally included in each parallel wiring.

As described above, since resistors R1 and R2 having different resistance values are provided in parallel wirings W_para1 and W_para2, respectively, RC circuits including parallel wirings W_para1 and W_para2 and piezoelectric element 16 have different time constants. In description below, an RC circuit including parallel wiring W_para1 having resistor R1 and piezoelectric element 16 will be referred to as a first RC circuit, and an RC circuit including parallel wiring W_para2 having resistor R2 and piezoelectric element 16 will be referred to as a second RC circuit.

In a case where load capacitance of piezoelectric element 16 is C [F], time constant τ1 [s] of the first RC circuit is expressed by Equation (1) below.

τ1=r1*C (1)

Further, time constant τ2 [s] of the second RC circuit is expressed by Equation (2) below.

τ2=r2*C (2)

Due to a difference in time constant between the first RC circuit and the second RC circuit, a phase difference occurs between signal S1 supplied from parallel wiring W_para1 to output wiring W_output and signal S2 supplied from parallel wiring W_para2 to output wiring W_output. Note that signal S1 and signal S2 have the same waveform including a noise component.

Here, if phases of signal S1 and signal S2 are set to be opposite to each other, that is, a phase of signal S1 and a phase of signal S2 can be shifted by 180 degrees, a noise component can be canceled in an output signal in which signal S1 and signal S2 are superimposed. In order to set phases of signal S1 and signal S2 to be opposite to each other, phases of signal S1 and signal S2 only need to be shifted by 180° (=360°/2), and an output timing of signal S1 and an output timing of signal S2 only need to be shifted by T/2 (as described above, T is noise period). In other words, in order to set signal S1 and signal S2 to be opposite in phase to each other, a difference between time constant τ1 and time constant τ2 only needs to be T/2.

Such a relationship between resistance values r1 and r2 is expressed by Equation (3) below.

(r2−r1)=T/2C (3)

For example, in a case where a noise period is 1 ns to 1 us and load capacitance C of piezoelectric element 16 is 200 pF to 20 nF, a resistance difference (r2−r1) between resistor R1 and resistor R2 only need to be set to about 0.025Ω to 2500Ω.

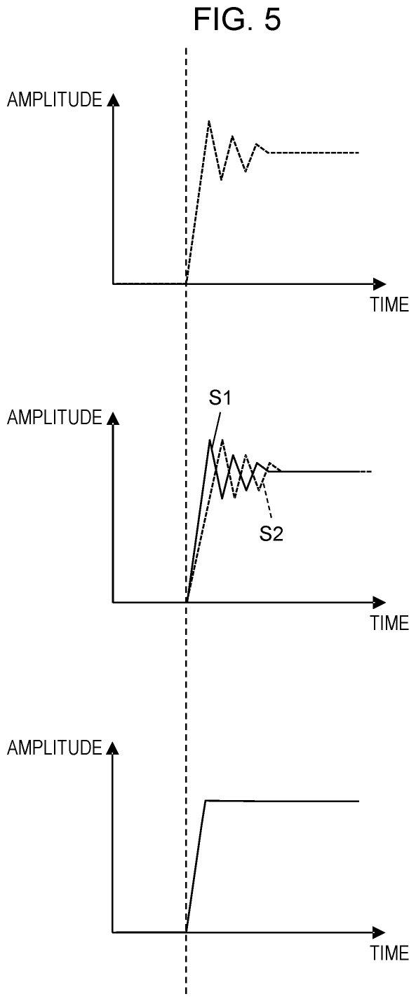

FIG. 5 is a diagram illustrating a signal at each position of noise reduction unit 17 in the first example of the configuration of noise reduction unit 17. A graph illustrated in an upper part of FIG. 5 illustrates an example of a waveform of a pulse signal input to input wiring W_input of phase controller 172. In a graph illustrated in a middle part of FIG. 5, an example of a waveform of signal S1 output from parallel wiring W_para1 is indicated by a solid line, and an example of a waveform of signal S2 output from parallel wiring W_para2 is indicated by a broken line. A graph illustrated in a lower part of FIG. 5 illustrates an example of a waveform of an output pulse signal in which signals S1 and S2 are superimposed and output. In each graph of FIG. 5, the vertical axis represents an amplitude value (voltage) of a signal, and the horizontal axis represents time.

As illustrated in the graph in an upper part of FIG. 5, a noise component of ringing noise included in a pulse signal input to input wiring W_input vibrates. As illustrated in the graph in a middle part of FIG. 5, a noise components of signals S1 and S2 output from parallel wirings W_para1 and W_para2 are in opposite phases to each other. As illustrated in the graph in a lower part of FIG. 5, in an output pulse signal in which signals S1 and S2 are superimposed, a noise component is canceled, and vibration of the signal caused by ringing noise is eliminated.

As described above, according to noise reduction unit 17, a resistance difference is provided between a plurality of resistors provided in a plurality of parallel wirings based on a noise period and load capacitance of piezoelectric element 16, and a phase of each pulse signal output from a plurality of parallel wirings is shifted. By the above, a noise component of each pulse signal output from a plurality of parallel wirings can be canceled, and a noise component included in an output pulse signal can be reduced.

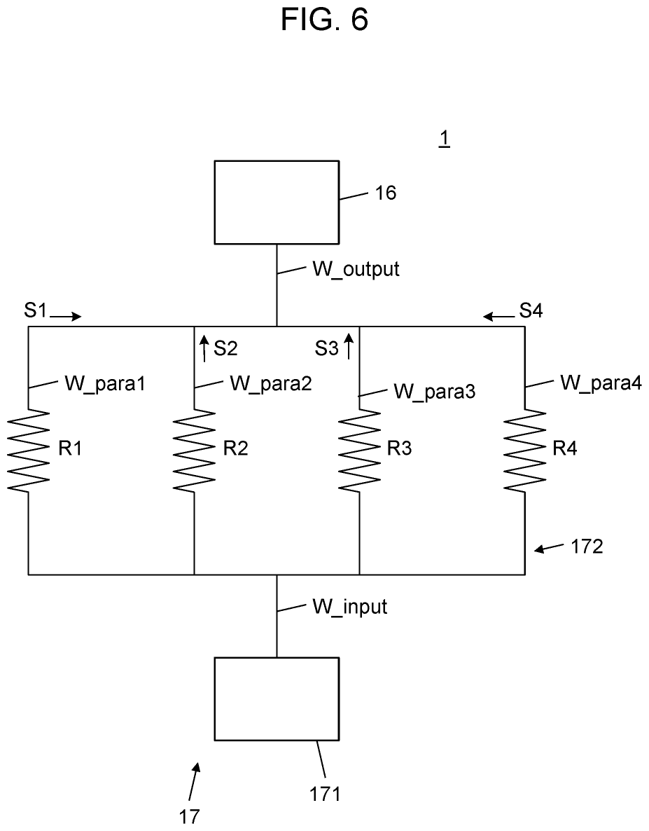

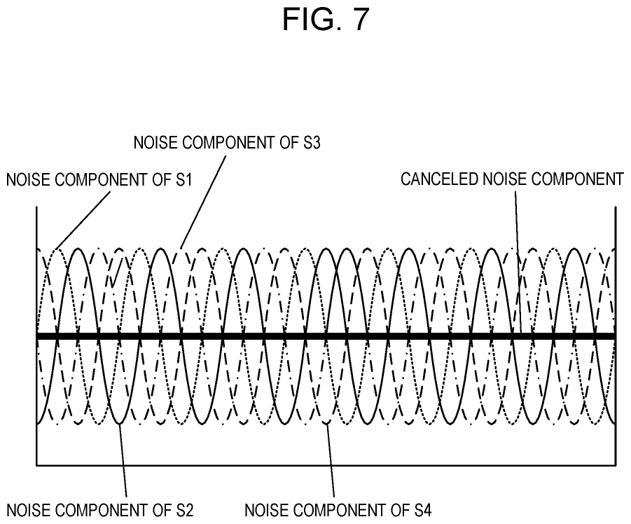

Note that, in the example illustrated in FIG. 4, phase controller 172 has two parallel wirings W_para1 and W_para2, but the present disclosure is not limited to this. For example, phase controller 172 may have four parallel wirings. FIG. 6 is a diagram illustrating a case where phase controller 172 has four parallel wirings in the first example of the configuration of noise reduction unit 17.

In this case, four parallel wirings W_para1, W_para2, W_para3, and W_para4 are assumed to have resistors R1, R2, R3, and R4, respectively, and output signals S1, S2, S3, and S4, respectively. In order to reduce a noise component in an output pulse signal in which signals S1, S2, S3, and S4 are superimposed, for example, phases only need to be shifted by 90° (=360°/4) between signals S1, S2, S3, and S4.

In this case, resistance values r1, r2, r3, and r4 of resistors R1, R2, R3, and R4 have a relationship below.

(r2−r1)=(r3−r2)=(r4−r3)=T/4C (4)

As such a resistance value is set, noise reduction unit 17 can reduce a noise component included in a generated pulse signal in an output pulse signal.

FIG. 7 is a diagram illustrating a noise component included in signals S1, S2, S3, and S4 output from four parallel wirings in the first example of the configuration of noise reduction unit 17. As illustrated in FIG. 7, signals S1, S2, S3, and S4 have timings shifted by T/4 and phases shifted by 90° (=360°/4), respectively. Therefore, as signals S1, S2, S3, and S4 are superimposed, noise components cancel each other and become zero. By the above, it is possible to substantially remove a noise component in an output pulse signal in which signals S1, S2, S3, and S4 are superimposed.

Note that, in the first example of the configuration of noise reduction unit 17, the number of parallel wirings included in the phase controller is not limited to two or four. The number of parallel wirings included in the phase controller may be plural. As the number of parallel wirings increases, performance of reducing noise of the noise reduction unit is improved, but manufacturing cost of the noise reduction unit increases. For this reason, the number of parallel wirings included in the phase controller is preferably, for example, between 2 and 20 (inclusive). In a case where the number of parallel wirings is N (N is an integer more than or equal to 2), phases of signals output from a plurality of parallel wirings only need to be shifted by 360°/N, and time constants of a plurality of RC circuits including a plurality of parallel wirings only need to be different by T/N.

Further, in the first example of the configuration of noise reduction unit 17, the case where no switch is provided on each parallel wiring is described. However, in the first example of the configuration of noise reduction unit 17, a switch may be provided on each parallel wiring. Alternatively, one switch may be provided on input wiring W_input. These switches may be turned on by, for example, a switch controller separately provided. In the first example, in a case where each of a plurality of parallel wirings has a switch, all the switches are preferably turned on at the same time.

### [Second Example of Configuration of Noise Reduction Unit 17]

In the first example of the configuration of noise reduction unit 17 described above, resistors of a plurality of parallel wirings of phase controller 172 have different resistance values. In this manner, time constants of RC circuits including a parallel wiring and a piezoelectric element are made different from each other, and noise between signals output from parallel wirings is canceled out. In a second example of the configuration of noise reduction unit 17 to be described below, each of a plurality of parallel wirings has a switch that operates independently. The switch can block transmission of a signal in each of a plurality of parallel wirings. By controlling a timing of turning on the switch, it is possible to cancel out noise between signals output from parallel wirings.

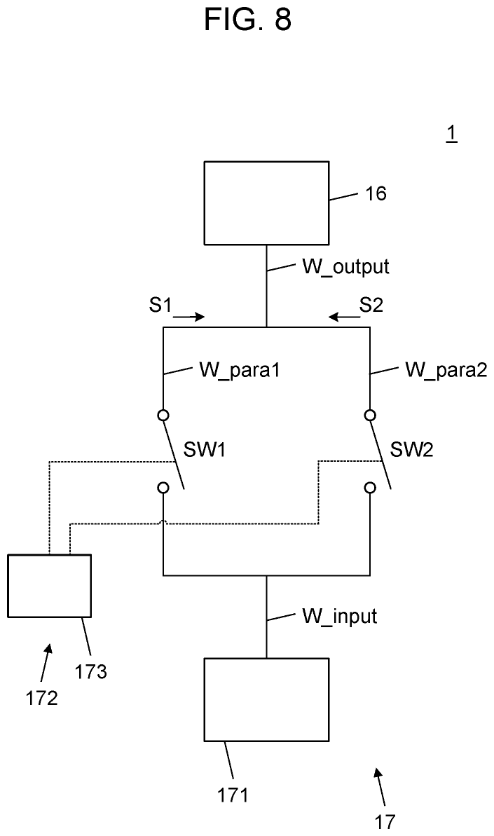

FIG. 8 is a diagram for explaining the second example of the configuration of noise reduction unit 17. In the second example illustrated in FIG. 8, similarly to the first example illustrated in FIG. 4, noise reduction unit 17 includes pulse generator 171 and phase controller 172 including input wiring W_input, parallel wirings W_para1 and W_para2, output wiring W_output, and switch controller 173.

As illustrated in FIG. 8, switches SW1 and SW2 are provided in parallel wirings W_para1 and W_para2, respectively. Each of switches SW1 and SW2 is controlled by switch controller 173. Switch controller 173 controls a timing of turning on switches SW1 and SW2 on the basis of known noise period T. In FIG. 8, each wiring is indicated by a solid line, and a signal line for switch controller 173 to control switches SW1 and SW2 is indicated by a broken line.

As described above, in order to make signal S1 output from parallel wiring W_para1 and signal S2 output from parallel wiring W_para2 opposite in phase to each other, an output timing of signal S1 and an output timing of signal S2 only need to be shifted by T/2 (as described above, T is a noise period). For this purpose, a timing at which switch SW1 is turned on and a timing at which switch SW2 is turned on only need to be shifted by T/2. Switch controller 173 controls a timing of turning on switch SW1 and a timing of turning on switch SW2 on the basis of noise period T stored in advance.

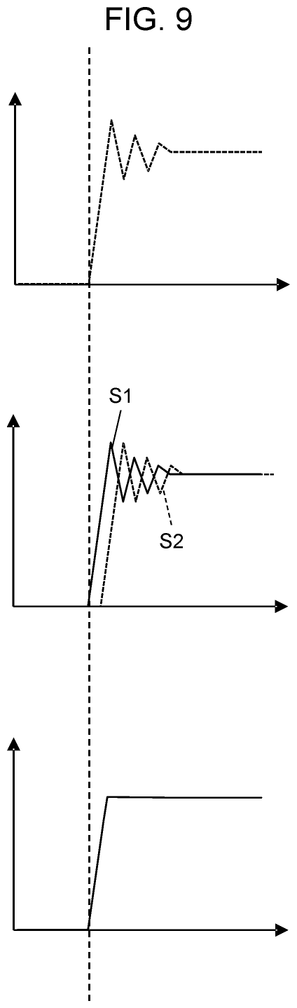

FIG. 9 is a diagram illustrating a signal at each position of noise reduction unit 17 in the second example of the configuration of noise reduction unit 17. A graph illustrated in an upper part of FIG. 9 illustrates an example of a waveform of a pulse signal before being input to input wiring W_input of phase controller 172. In a graph illustrated in a middle part of FIG. 9, an example of a waveform of signal S1 output from parallel wiring W_para1 is indicated by a solid line, and an example of a waveform of signal S2 output from parallel wiring W_para2 is indicated by a broken line. A graph illustrated in a lower part of FIG. 9 illustrates an example of a waveform of an output pulse signal in which signals S1 and S2 are superimposed and output. In each graph of FIG. 9, the vertical axis represents an amplitude value (voltage) of a signal, and the horizontal axis represents time.

As illustrated in the graph in an upper part of FIG. 9, a noise component of ringing noise included in a pulse signal input to input wiring W_input vibrates. As illustrated in the graph in a middle part of FIG. 9, output timings of signals S1 and S2 output from parallel wirings W_para1 and W_para2 are shifted from each other, and noise components of signals S1 and S2 are in opposite phases to each other. As illustrated in the graph in a lower part of FIG. 9, in an output pulse signal in which signals S1 and S2 are superimposed, a noise component is canceled, and vibration of the signal caused by ringing noise is eliminated.

As described above, according to noise reduction unit 17, switch controller 173 controls a timing of turning on a switch provided in each parallel wiring. In this manner, phases of pulse signals output from a plurality of parallel wirings are shifted. By the above, a noise component of each pulse signal output from a plurality of parallel wirings can be canceled, and a noise component included in an output pulse signal can be reduced.

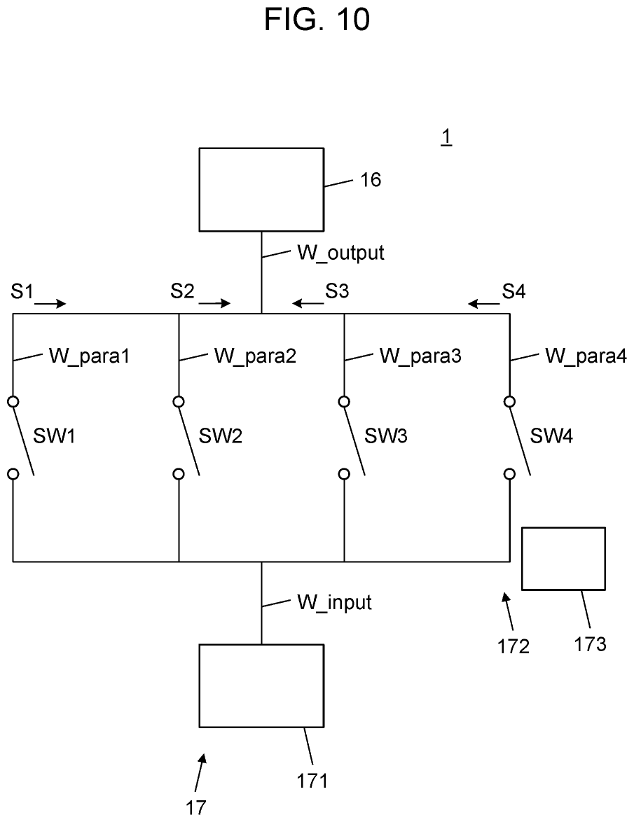

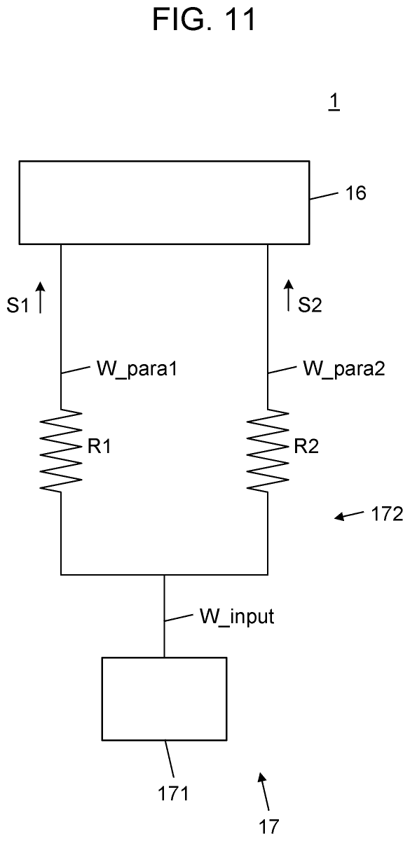

Also in the second example of noise reduction unit 17, similarly to the first example described above, the number of parallel wirings is not limited to two, and may be plural (for example, between 2 and 20 (inclusive)). FIG. 10 is a diagram illustrating a configuration example in a case where phase controller 172 has four parallel wirings in the second example of the configuration of noise reduction unit 17. Note that, in FIG. 10, illustration of a signal line for switch controller 173 to control switches SW1 and SW2 is omitted.

As illustrated in FIG. 10, in a case where the number of parallel wirings included in phase controller 172 is four, timings at which switches SW1, SW2, SW3, and SW4 provided in parallel wirings are turned on only need to be shifted from each other by T/4. Further, in a case where the number of parallel wirings is N (N is an integer more than or equal to 2), timings at which switches provided in parallel wirings are turned on only need to be shifted from each other by T/N. By the above, phases between signals output by N parallel wirings included in phase controller 172 can be shifted by 360°/N, and noise components are allowed to cancel each other when all the signals are superimposed. Therefore, noise reduction unit 17 can output an output pulse signal in which a noise component is reduced to piezoelectric element 16.

Note that, in the second example of noise reduction unit 17, each parallel wiring is described to have no resistor. In practice, it is preferable to set wiring resistors of a plurality of parallel wirings to have the same value by configuring each parallel wiring with electric wires of the same material, the same length, and the same thickness. Further, a plurality of parallel wirings may separately have a resistor having the same resistance value in addition to the wiring resistor.

### [Third Example of Configuration of Noise Reduction Unit 17]

In the first and second examples of the configuration of noise reduction unit 17 described above, in phase controller 172, a plurality of parallel wirings form a parallel circuit, and the parallel circuit is connected in series to piezoelectric element 16 by one output wiring W_output. In a third example of the configuration of noise reduction unit 17 described below, a plurality of parallel wirings are directly connected to piezoelectric element 16. FIG. 11 is a diagram for explaining the third example of the configuration of noise reduction unit 17.

As in the third example, in a case where a signal output from a plurality of parallel wirings is directly input to piezoelectric element 16, piezoelectric element 16 operates without any problem. Further, since a displacement timing and a displacement amount of piezoelectric element 16 are determined by an input signal, in the third example, similarly to the first example and the second example, it is possible to prevent piezoelectric element 16 from having a discharge failure due to influence of ringing noise.

### [Manufacturing Method]

The inkjet apparatus including noise reduction unit 17 described above is manufactured by, for example, a manufacturing method below.

First, various plate members such as nozzle plate 12, side wall 13 forming pressure chamber 15, and diaphragm 14 are manufactured by laser processing, etching, or the like.

Next, the various plate members are bonded using a thermosetting adhesive or the like.

Finally, piezoelectric element 16 to which a drive wiring is connected is bonded to diaphragm 14. Furthermore, noise reduction unit 17 including pulse generator 171 and phase controller 172 is connected to piezoelectric element 16. By the above, inkjet apparatus 1 is manufactured.

### [Another Variation]

In the above-described exemplary embodiment, noise reduction unit 17 includes one pulse generator 171, and a generated pulse signal generated by pulse generator 171 is branched into a plurality of parallel wirings included in phase controller 172. In the inkjet apparatus according to the present disclosure, for example, the noise reduction unit may include a plurality of pulse generators.

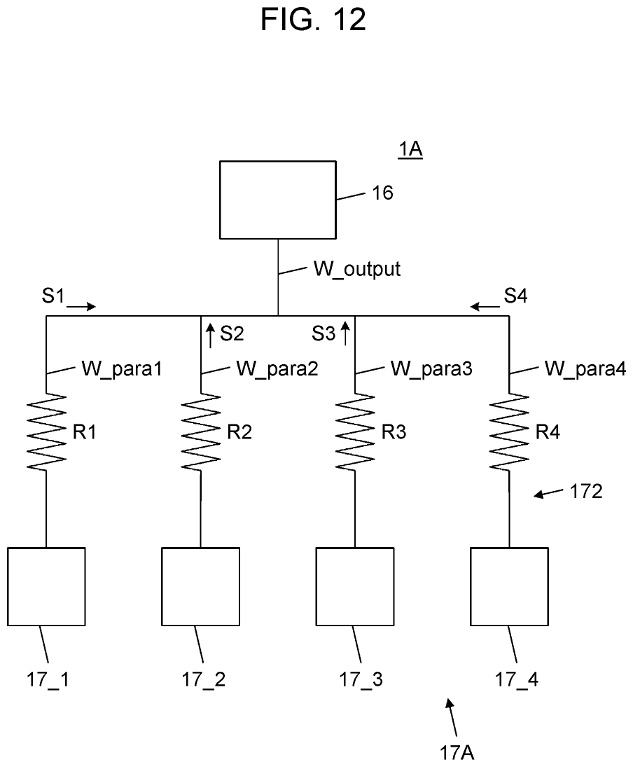

FIG. 12 is a view for explaining a variation of the inkjet apparatus provided with a plurality of pulse generators. In the variation illustrated in FIG. 12, in inkjet apparatus 1A, noise reduction unit 17A includes four pulse generators 171_1, 171_2, 171_3, 171_4.

In the variation illustrated in FIG. 12, pulse signals generated by a plurality of pulse generators 171_1, 171_2, 171_3, 171_4 are input to four parallel wirings included in phase controller 172. In this case, for example, when timings at which generated pulse signals generated by a plurality of pulse generators 171_1, 171_2, 171_3, 171_4 are transmitted to their parallel wirings are shifted by T/4 from each other, similarly to the above-described exemplary embodiment, phases between signals output from N parallel wirings of noise reduction unit 17 can be shifted by 360°/N from each other, and an output pulse signal with a reduced noise component can be output to piezoelectric element 16.

Note that, in the present variation, the number of pulse generators is not limited to four, and only needs to be the same as the number of a plurality of parallel wirings included in phase controller 172.

Furthermore, in the above-described exemplary embodiment, noise reduction units 17 and 17A have a configuration in which phases can be shifted by 360°/N from each other so that a noise component can be canceled out by N parallel wirings. However, in the present disclosure, the noise reduction unit does not need to necessarily include a plurality of parallel wirings by which phases can be shifted by 360°/N from each other.

For example, if there is a phase difference between at least one signal among signals output from N parallel wirings and another signal, a noise component can be reduced if not canceled out in a superimposed output pulse signal. More specifically, in the inkjet apparatus of the present disclosure, when at least one resistance value among resistance values of a plurality of parallel wirings included in the noise reduction unit is different, a noise component can be reduced by the noise reduction unit. Alternatively, if an on timing of at least one of switches provided in a plurality of parallel wirings included in the noise reduction unit is shifted, a noise component can be reduced by the noise reduction unit. Alternatively, in a case where a plurality of pulse generators are connected to a plurality of parallel wirings, a generated pulse signal only needs to be transmitted to at least one wiring of a plurality of parallel wirings at a timing different from another wiring.

### Action, Effect

Inkjet apparatus 1 (1A) according to the present disclosure includes piezoelectric element 16 that is driven by a pulse signal and applies pressure to pressure chamber 15 containing ink, and phase controller 172 that includes N (N is an integer more than or equal to 2) parallel wirings provided in parallel with each other and shifts a phase of the pulse signal transmitted by each of the parallel wirings.

With such a configuration, since a noise component is reduced in an output pulse signal output from phase controller 172 to piezoelectric element 16, if a displacement amount and a displacement speed of piezoelectric element 16 are increased, piezoelectric element 16 can be caused to perform stable operation. As a result, a high-viscosity ink material can be stably discharged in a large droplet.

According to inkjet apparatus 1 of the present disclosure, at least one resistance value among resistance values of the N parallel wirings is different from another resistance value. Specifically, a resistance value of the N parallel wirings is set such that phases of the pulse signals transmitted by the parallel wirings are shifted by 360°/N.

Alternatively, according to inkjet apparatus 1 according to the present disclosure, phase controller 172 includes a switch that blocks transmission of a pulse signal in at least one of the N parallel wirings. Specifically, each of the N parallel wirings includes a switch, and switch controller 173 that turns on the switch to shift phases of pulse signals transmitted by the parallel wirings by 360°/N is further included.

If any of such configurations is employed, phase controller 172 shifts a phase of an input generated pulse signal and superimposes the generated pulse signal to obtain an output pulse signal. For this reason, it is possible to cancel out and reduce or reduce a noise component included in a generated pulse signal.

Further, inkjet apparatus 1A according to the present disclosure further includes a plurality of pulse generators 171 that generate pulse signals at different timings, and a plurality of pulse generators 171 transmits a pulse signal to at least one of the N parallel wirings at a timing different from a timing of another parallel wiring.

If any of such configurations is employed, phase controller 172 shifts a phase of an input generated pulse signal by 360°/N and superimposes the generated pulse signal to obtain an output pulse signal. For this reason, it is possible to cancel out and reduce a noise component included in a generated pulse signal.

Printer 100 according to the present disclosure includes inkjet apparatus 1 described above, movement device 2 that relatively moves inkjet apparatus 1 and a printing target, and controller 3 that controls inkjet apparatus 1 and movement device 2.

According to such printer 100, an ink material having a high viscosity can be stably discharged in a large droplet, and thus printer 100 can be applied to a wide variety of printing applications.

According to the present disclosure, a high-viscosity ink material can be stably discharged in a large droplet.

The present disclosure is useful for an inkjet apparatus that discharges ink by displacement of a piezoelectric element.

What is claimed is:

1. An inkjet apparatus comprising:
a piezoelectric element that is driven by a pulse signal and applies pressure to a pressure chamber containing ink; and
a phase controller that includes N parallel wirings provided in parallel with each other, where N is an integer more than or equal to 2, and shifts a phase of the pulse signal transmitted by each of the N parallel wirings.

2. The inkjet apparatus according to claim 1, wherein at least one resistance value among resistance values of the N parallel wirings is different from another resistance value.

3. The inkjet apparatus according to claim 2, wherein the resistance values of the N parallel wirings are set to shift phases of pulse signals transmitted by the N parallel wirings to be by 360°/N.

4. The inkjet apparatus according to claim 1, wherein the phase controller includes a switch that blocks transmission of the pulse signal in at least one of the N parallel wirings.

5. The inkjet apparatus according to claim 4, wherein the phase controller further includes a switch controller that turns on the switch to shift phases of pulse signals transmitted by the N parallel wirings by 360°/N.

6. The inkjet apparatus according to claim 1, wherein the N parallel wirings form a parallel circuit, and the parallel circuit is connected in series to the piezoelectric element.

7. The inkjet apparatus according to claim 1, further comprising a plurality of pulse generators that generate the pulse signal at a different timing, wherein the plurality of pulse generators transmit the pulse signal to at least one of the N parallel wirings at a timing different from a timing of another one of the N parallel wirings.

8. A printer comprising:
the inkjet apparatus according to claim 1;
a movement device that moves a printing target relative to the inkjet apparatus; and
a controller that controls the inkjet apparatus and the movement device.
